(19) United States
(12) Patent Application Publication
(10) Pub. No.: US 2013/0179755 A1
(43) Pub. Date: Jul. 11, 2013

(54) SYSTEMS AND METHODS FOR LOW DENSITY PARITY CHECK TONE MAPPING

(71) Applicant: QUALCOMM Incorporated, San Diego, CA (US)

(72) Inventors: Lin Yang, San Diego, CA (US); Didier Johannes Richard Van Nee, De Meern (NL); Hemanth Sampath, San Diego, CA (US); Sameer Vermani, San Diego, CA (US)

(73) Assignee: QUALCOMM Incorporated, San Diego, CA (US)

(21) Appl. No.: 13/735,747

(22) Filed: Jan. 7, 2013

Related U.S. Application Data
(60) Provisional application No. 61/585,474, filed on Jan. 11, 2012.

(51) Int. Cl. H03M 13/13

(52) U.S. Cl. CPC H03M 13/13
USPC 714/776

(57) ABSTRACT

This disclosure provides systems, methods, and apparatus, including non-transitory computer-readable medium for tone mapping an error correction code for 1 MHz OFDM transmission. In one aspect, a wireless communications apparatus is provided. The wireless communications apparatus includes a tone mapper configured to tone map at least error correction codeword to data tones of an orthogonal frequency-division multiplexing (OFDM) symbol based on an error correction code tone mapping distance selected from the group consisting of 2, 3, and 4. The OFDM symbol has twenty four data tones, at least one pilot tone, a DC tone, and at least one guard tone. The wireless communications apparatus further includes a transmit module configured to transmit the at least one tone mapped error correction codeword using about a 1 MHz OFDM transmission mode.

### CROSS-REFERENCE TO RELATED APPLICATIONS

This application claims priority under 35 U.S.C. §119(e) to U.S. Provisional Patent Application No. 61/585,474, entitled “SYSTEMS AND METHODS FOR LOW DENSITY PARITY CHECK TONE MAPPING” and filed on Jan. 11, 2012, the entire contents of which disclosure is herewith incorporated by reference.

### BACKGROUND

1. FIELD

The present application relates generally to wireless communications, and more specifically to systems, methods, and devices for tone mapping. Certain aspects herein relate to providing tone mapping for 1 MHz OFDM transmission.

2. Background

In many telecommunication systems, communications networks are used to exchange messages among several interacting spatially-separated devices. Networks may be classified according to geographic scope, which could be, for example, a metropolitan area, a local area, or a personal area. Such networks would be designated respectively as a wide area network (WAN), metropolitan area network (MAN), local area network (LAN), or personal area network (PAN). Networks also differ according to the switching/routing technique used to interconnect the various network nodes and devices (e.g., circuit switching vs. packet switching), the type of physical media employed for transmission (e.g., wired vs. wireless), and the set of communication protocols used (e.g., Internet protocol suite, SONET (Synchronous Optical Networking), Ethernet, etc.).

Wireless networks are often preferred when the network elements are mobile and thus have dynamic connectivity needs, or if the network architecture is formed in an ad hoc, rather than fixed, topology. Wireless networks employ intangible physical media in an unguided propagation mode using electromagnetic waves in the radio, microwave, infra-red, optical, etc. frequency bands. Wireless networks advantageously facilitate user mobility and rapid field deployment when compared to fixed wired networks.

The devices in a wireless network may transmit/receive information between each other. The information may comprise packets, which in some aspects may be referred to as data units. The packets may include overhead information (e.g., header information, packet properties, etc.) that helps in routing the packet through the network, identifying the data in the packet, processing the packet, etc., as well as data, for example user data, multimedia content, etc. as might be carried in a payload of the packet.

### SUMMARY

The systems, methods, and devices of the invention each have several aspects, no single one of which is solely responsible for its desirable attributes. Without limiting the scope of this invention as expressed by the claims which follow, some features will now be discussed briefly. After considering this discussion, and particularly after reading the section entitled “Detailed Description” one will understand how the features of this invention provide advantages that include tone mapping using 1 MHz orthogonal frequency-division multiplexing (OFDM) transmission.

One aspect of the disclosure provides a wireless communications apparatus. The wireless communications apparatus includes a tone mapper configured to tone map at least error correction codeword to data tones of an OFDM symbol based on an error correction code tone mapping distance selected from the group consisting of 2, 3, and 4. The OFDM symbol has twenty four data tones, at least one pilot tone, a DC tone, and at least one guard tone. The wireless communications apparatus further includes a transmit module configured to transmit the at least one tone mapped error correction codeword for transmission using about a 1 MHz OFDM transmission mode.

Another aspect of the disclosure provides an implementation of a method for tone mapping data for wireless transmission. The method includes tone mapping at least one error correction codeword to data tones of an OFDM symbol based on an error correction code tone mapping distance selected from the group consisting of 2, 3, and 4. The OFDM symbol has twenty four data tones, at least one pilot tone, a DC tone, and at least one guard tone. The method further includes transmitting the at least one tone mapped error correction codeword using about a 1 MHz OFDM transmission mode.

Yet another aspect of the disclosure provides a wireless communications apparatus. The wireless communications apparatus includes means for tone mapping at least one error correction codeword to data tones of an OFDM symbol based on an error correction code tone mapping distance selected from the group consisting of 2, 3, and 4. The OFDM symbol has twenty four data tones, at least one pilot tone, a DC tone, and at least one guard tone. The wireless communications apparatus further includes means for transmitting the at least one tone mapped error correction codeword using about a 1 MHz OFDM transmission mode.

Another aspect of the disclosure provides a non-transitory computer-readable medium comprising code that, when executed, causes an apparatus to tone map at least one error correction codeword to data tones of an OFDM symbol based on an error correction code tone mapping distance selected from the group consisting of 2, 3, and 4. The OFDM symbol has twenty four data tones, at least one pilot tone, a DC tone, and at least one guard tone. The medium further comprises code that, when executed, causes the apparatus to transmit the at least one tone mapped error correction codeword using about a 1 MHz OFDM transmission mode.

Another aspect of the disclosure provides a wireless communications apparatus. The wireless communications apparatus includes a receive module configured to receive at least one tone mapped error correction codeword using about a 1 MHz OFDM transmission mode. The wireless communications apparatus further includes a tone de-mapper configured to tone de-map the at least one tone mapped error correction codeword from data tones of an OFDM symbol based on an error correction code tone mapping distance selected from the group consisting of 2, 3, and 4. The OFDM symbol has twenty four data tones, at least one pilot tone, a DC tone, and at least one guard tone.

Another aspect of the disclosure provides an implementation of a method for tone de-mapping data. The method includes receiving at least one tone mapped error correction codeword using about a 1 MHz OFDM transmission mode. The method further includes tone de-mapping the at least one tone mapped error correction codeword from data tones of an OFDM symbol based on an error correction code tone mapping distance selected from the group consisting of 2, 3, and 4. The OFDM symbol has twenty four data tones, at least one pilot tone, a DC tone, and at least one guard tone.

Another aspect of the disclosure provides a wireless communications apparatus. The wireless communications apparatus includes means for receiving at least one tone mapped error correction codeword using about a 1 MHz OFDM transmission mode. The wireless communications apparatus further includes means for tone de-mapping the at least one tone mapped error correction codeword from data tones of an OFDM symbol based on an error correction code tone mapping distance selected from the group consisting of 2, 3, and 4. The OFDM symbol has twenty four data tones, at least one pilot tone, a DC tone, and at least one guard tone.

Another aspect of the disclosure provides a non-transitory computer-readable medium comprising code that, when executed, causes an apparatus to receive at least one tone mapped error correction codeword using about a 1 MHz OFDM transmission mode. The medium further comprises code that, when executed, causes an apparatus to tone de-map the at least one tone mapped error correction codeword from data tones of an OFDM symbol based on an error correction code tone mapping distance selected from the group consisting 2, 3, and 4. The OFDM symbol has twenty four data tones, at least one pilot tone, a DC tone, and at least one guard tone.

Another aspect of the disclosure provides a wireless communications apparatus. The wireless communications apparatus includes a tone mapper configured to tone map at least one error correction codeword to data tones of an OFDM symbol based on an error correction code tone mapping distance of 4. The OFDM symbol has data tones, at least one pilot tone, a DC tone, and at least one guard tone. The wireless communications apparatus further includes a transmit module configured to transmit the at least one tone mapped error correction codeword for transmission using about a 2 MHz OFDM transmission mode and using a 64 point IFFT module.

Another aspect of the disclosure provides an implementation of a method for tone mapping data for wireless transmission. The method includes tone mapping at least one error correction codeword to data tones of an OFDM symbol based on an error correction code tone mapping distance of 4. The OFDM symbol has data tones, at least one pilot tone, a DC tone, and at least one guard tone. The method further includes transmitting the at least one tone mapped error correction codeword using about a 2 MHz OFDM transmission mode and using a 64 point IFFT module.

Another aspect of the disclosure provides a wireless communications apparatus. The wireless communications apparatus includes means for tone mapping at least one error correction codeword to data tones of an OFDM symbol based on an error correction code tone mapping distance of 4. The OFDM symbol has data tones, at least one pilot tone, a DC tone, and at least one guard tone. The wireless communications apparatus further includes means for transmitting the at least one tone mapped error correction codeword using about a 2 MHz OFDM transmission mode and using a 64 point IFFT module.

Another aspect of the disclosure provides a non-transitory computer-readable medium comprising code that, when executed, causes an apparatus to tone map at least one error correction codeword to data tones of an OFDM symbol based on an error correction code tone mapping distance of 4. The OFDM symbol has data tones, at least one pilot tone, a DC tone, and at least one guard tone. The medium further comprises code that, when executed, causes the apparatus to transmit the at least one tone mapped error correction codeword using about a 2 MHz OFDM transmission mode and using a 64 point IFFT module.

Another aspect of the disclosure provides a wireless communications apparatus. The wireless communications apparatus includes a receive module configured to receive at least one tone mapped error correction codeword using about a 2 MHz OFDM transmission mode and using a 64 point FFT module. The wireless communications apparatus further includes a tone de-mapper configured to tone de-map the at least one tone mapped error correction codeword from data tones of an OFDM symbol based on an error correction code tone mapping distance of 4. The OFDM symbol has data tones, at least one pilot tone, a DC tone, and at least one guard tone.

Another aspect of the disclosure provides an implementation of a method for tone de-mapping data. The method includes receiving at least one tone mapped error correction codeword using about a 2 MHz OFDM transmission mode and using a 64 point FFT module. The method further includes tone de-mapping the at least one tone mapped error correction codeword from data tones of an OFDM symbol based on an error correction code tone mapping distance of 4. The OFDM symbol has data tones, at least one pilot tone, a DC tone, and at least one guard tone

Another aspect of the disclosure provides a wireless communications apparatus. The wireless communications apparatus includes means for receiving at least one tone mapped error correction codeword using about a 2 MHz OFDM transmission mode and using a 64 point FFT module. The wireless communications apparatus further includes means for tone de-mapping the at least one tone mapped error correction codeword from data tones of an OFDM symbol based on an error correction code tone mapping distance of 4. The OFDM symbol has data tones, at least one pilot tone, a DC tone, and at least one guard tone.

Another aspect of the disclosure provides a non-transitory computer-readable medium comprising code that, when executed, causes an apparatus to receive at least one tone mapped error correction codeword using about a 2 MHz OFDM transmission mode and using a 64 point FFT module. The medium further comprises code that, when executed, causes an apparatus to tone de-map the at least one tone mapped error correction codeword from data tones of an OFDM symbol based on an error correction code tone mapping distance of 4. The OFDM symbol has data tones, at least one pilot tone, a DC tone, and at least one guard tone.

### BRIEF DESCRIPTION OF THE DRAWINGS

FIG. 1 illustrates an example of a wireless communication system in which aspects of the present disclosure may be employed.

FIG. 2 shows a functional block diagram of an exemplary wireless device that may be employed within the wireless communication system of FIG. 1.

FIG. 3 shows a functional block diagram of exemplary components that may be utilized in the wireless device of FIG. 2 to transmit wireless communications.

FIG. 4 shows a functional block diagram of exemplary components that may be utilized in the wireless device of FIG. 2 to receive wireless communications.

FIG. 5 is a functional block diagram of a system that may be implemented in wireless devices such as the wireless device of FIG. 2 to transmit and receive wireless communications.

FIG. 6 shows a flow chart of an exemplary method for tone mapping and transmitting a data unit.

FIG. 7 shows a flow chart of an exemplary method for receiving and tone de-mapping a data unit.

FIG. 8 is a functional block diagram of another exemplary wireless device that may be employed within the wireless communication system of FIG. 1.

FIG. 9 is a functional block diagram of yet another exemplary wireless device that may be employed within the wireless communication system of FIG. 1.

FIG. 10 shows a flow chart of an exemplary method for tone mapping and transmitting a data unit.

FIG. 11 shows a flow chart of an exemplary method for receiving and tone de-mapping a data unit.

FIG. 12 is a functional block diagram of another exemplary wireless device that may be employed within the wireless communication system of FIG. 1.

FIG. 13 is a functional block diagram of yet another exemplary wireless device that may be employed within the wireless communication system of FIG. 1.

### DETAILED DESCRIPTION

Various aspects of the novel systems, apparatuses, and methods are described more fully hereinafter with reference to the accompanying drawings. The teachings disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the novel systems, apparatuses, and methods disclosed herein, whether implemented independently of or combined with any other aspect of the invention. For example, an apparatus may be implemented or a method may be practiced using any number of the aspects set forth herein. In addition, the scope of the invention is intended to cover such an apparatus or method which is practiced using other structure, functionality, or structure and functionality in addition to or other than the various aspects of the invention set forth herein. It should be understood that any aspect disclosed herein may be embodied by one or more elements of a claim.

Although particular aspects are described herein, many variations and permutations of these aspects fall within the scope of the disclosure. Although some benefits and advantages of the preferred aspects are mentioned, the scope of the disclosure is not intended to be limited to particular benefits, uses, or objectives. Rather, aspects of the disclosure are intended to be broadly applicable to different wireless technologies, system configurations, networks, and transmission protocols, some of which are illustrated by way of example in the figures and in the following description of the preferred aspects. The detailed description and drawings are merely illustrative of the disclosure rather than limiting, the scope of the disclosure being defined by the appended claims and equivalents thereof.

Wireless network technologies may include various types of wireless local area networks (WLANs). A WLAN may be used to interconnect nearby devices together, employing widely used networking protocols. The various aspects described herein may apply to any communication standard, such as WiFi or, more generally, any member of the IEEE 802.11 family of wireless protocols. For example, the various aspects described herein may be used as part of the IEEE 802.11ah protocol, which uses sub-1 GHz bands.

In some aspects, wireless signals in a sub-gigahertz band may be transmitted according to the 802.11ah protocol using orthogonal frequency-division multiplexing (OFDM), direct-sequence spread spectrum (DSSS) communications, a combination of OFDM and DSSS communications, or other schemes. Implementations of the 802.11ah protocol may be used for sensors, metering, and smart grid networks. Advantageously, aspects of certain devices implementing the 802.11ah protocol may consume less power than devices implementing other wireless protocols, and/or may be used to transmit wireless signals across a relatively long range, for example about one kilometer or longer.

In some implementations, a WLAN includes various devices which are the components that access the wireless network. For example, there may be two types of devices: access points (“APs”) and clients (also referred to as stations, or “STAs”). In general, an AP serves as a hub or base station for the WLAN and an STA serves as a user of the WLAN. For example, an STA may be a laptop computer, a personal digital assistant (PDA), a mobile phone, etc. In an example, an STA connects to an AP via a WiFi (e.g., IEEE 802.11 protocol such as 802.11ah) compliant wireless link to obtain general connectivity to the Internet or to other wide area networks. In some implementations an STA may also be used as an AP.

An access point (“AP”) may also comprise, be implemented as, or known as a NodeB, Radio Network Controller (“RNC”), eNodeB, Base Station Controller (“BSC”), Base Transceiver Station (“BTS”), Base Station (“BS”), Transceiver Function (“TF”), Radio Router, Radio Transceiver, or some other terminology.

A station “STA” may also comprise, be implemented as, or known as an access terminal (“AT”), a subscriber station, a subscriber unit, a mobile station, a remote station, a remote terminal, a user terminal, a user agent, a user device, user equipment, or some other terminology. In some implementations an access terminal may comprise a cellular telephone, a cordless telephone, a Session Initiation Protocol (“SIP”) phone, a wireless local loop (“WLL”) station, a personal digital assistant (“PDA”), a handheld device having wireless connection capability, or some other suitable processing device connected to a wireless modem. Accordingly, one or more aspects taught herein may be incorporated into a phone (e.g., a cellular phone or smartphone), a computer (e.g., a laptop), a portable communication device, a headset, a portable computing device (e.g., a personal data assistant), an entertainment device (e.g., a music or video device, or a satellite radio), a gaming device or system, a global positioning system device, or any other suitable device that is configured to communicate via a wireless medium.

As discussed above, certain of the devices described herein may implement the 802.11ah standard, for example. Such devices, whether used as an STA or AP or other device, may be used for smart metering or in a smart grid network. Such devices may provide sensor applications or be used in home automation. The devices may instead or in addition be used in a healthcare context, for example for personal healthcare. They may also be used for surveillance, to enable extended-range Internet connectivity (e.g., for use with hotspots), or to implement machine-to-machine communications.

Certain of the devices described herein may further implement Multiple Input Multiple Output (MIMO) technology and be implemented as part of the 802.11ah standard. A MIMO system employs multiple (N_{T}) transmit antennas and multiple (N_{R}) receive antennas for data transmission. A MIMO channel formed by the N_{T} transmit and N_{R} receive antennas may be decomposed into N_{S} independent channels, which are also referred to as spatial channels, where N_{S}≦min {N_{T}, N_{R}}. Each of the N_{S} independent channels corresponds to a dimension. The MIMO system can provide improved performance (e.g., higher throughput and/or greater reliability) if the additional dimensionalities created by the multiple transmit and receive antennas are utilized.

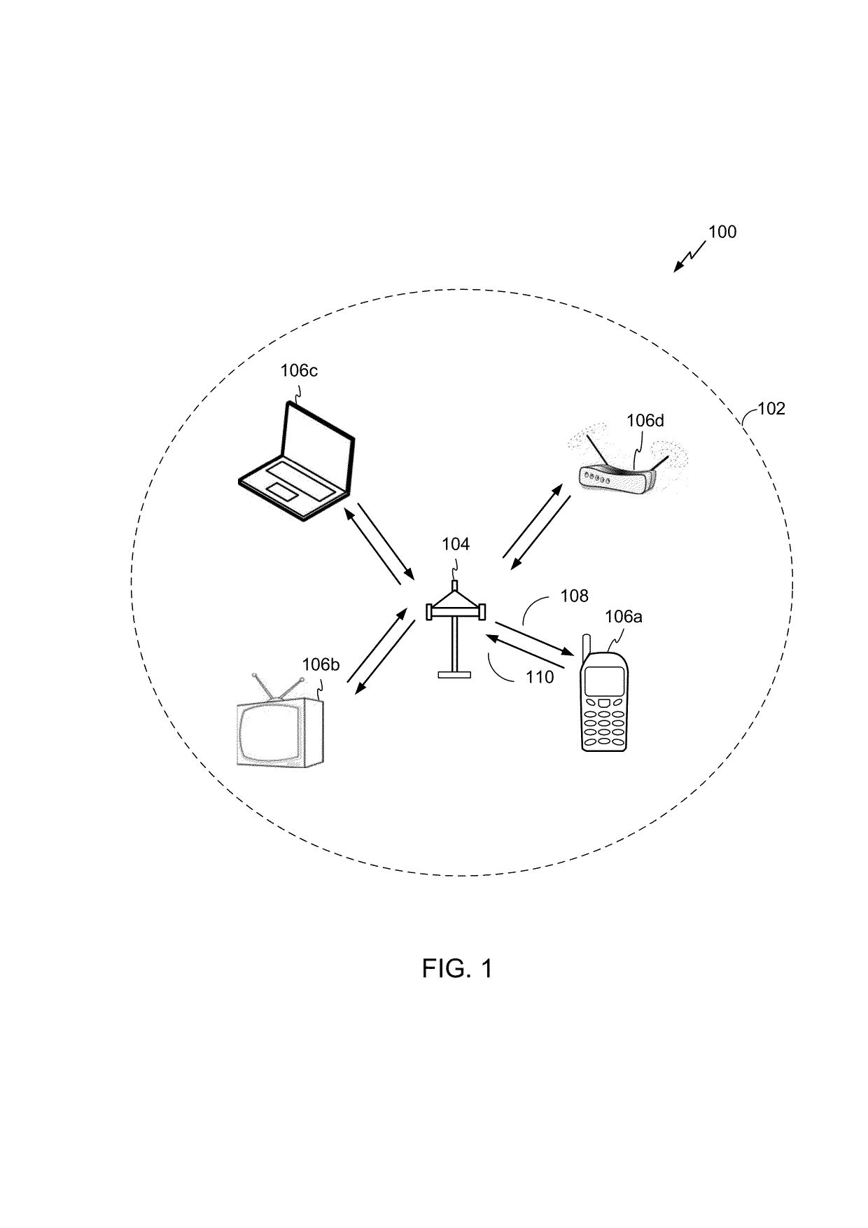

FIG. 1 illustrates an example of a wireless communication system 100 in which aspects of the present disclosure may be employed. The wireless communication system 100 may operate pursuant to a wireless standard, for example the 802.11ah standard. The wireless communication system 100 may include an AP 104, which communicates with STAs 106.

A variety of processes and methods may be used for transmissions in the wireless communication system 100 between the AP 104 and the STAs 106. For example, signals may be sent and received between the AP 104 and the STAs 106 in accordance with OFDM/OFDMA techniques. If this is the case, the wireless communication system 100 may be referred to as an OFDM/OFDMA system. Alternatively, signals may be sent and received between the AP 104 and the STAs 106 in accordance with CDMA techniques. If this is the case, the wireless communication system 100 may be referred to as a CDMA system.

A communication link that facilitates transmission from the AP 104 to one or more of the STAs 106 may be referred to as a downlink (DL) 108, and a communication link that facilitates transmission from one or more of the STAs 106 to the AP 104 may be referred to as an uplink (UL) 110. Alternatively, a downlink 108 may be referred to as a forward link or a forward channel, and an uplink 110 may be referred to as a reverse link or a reverse channel.

The AP 104 may act as a base station and provide wireless communication coverage in a basic service area (BSA) 102. The AP 104 along with the STAs 106 associated with the AP 104 and that use the AP 104 for communication may be referred to as a basic service set (BSS). It should be noted that the wireless communication system 100 may not have a central AP 104, but rather may function as a peer-to-peer network between the STAs 106. Accordingly, the functions of the AP 104 described herein may alternatively be performed by one or more of the STAs 106.

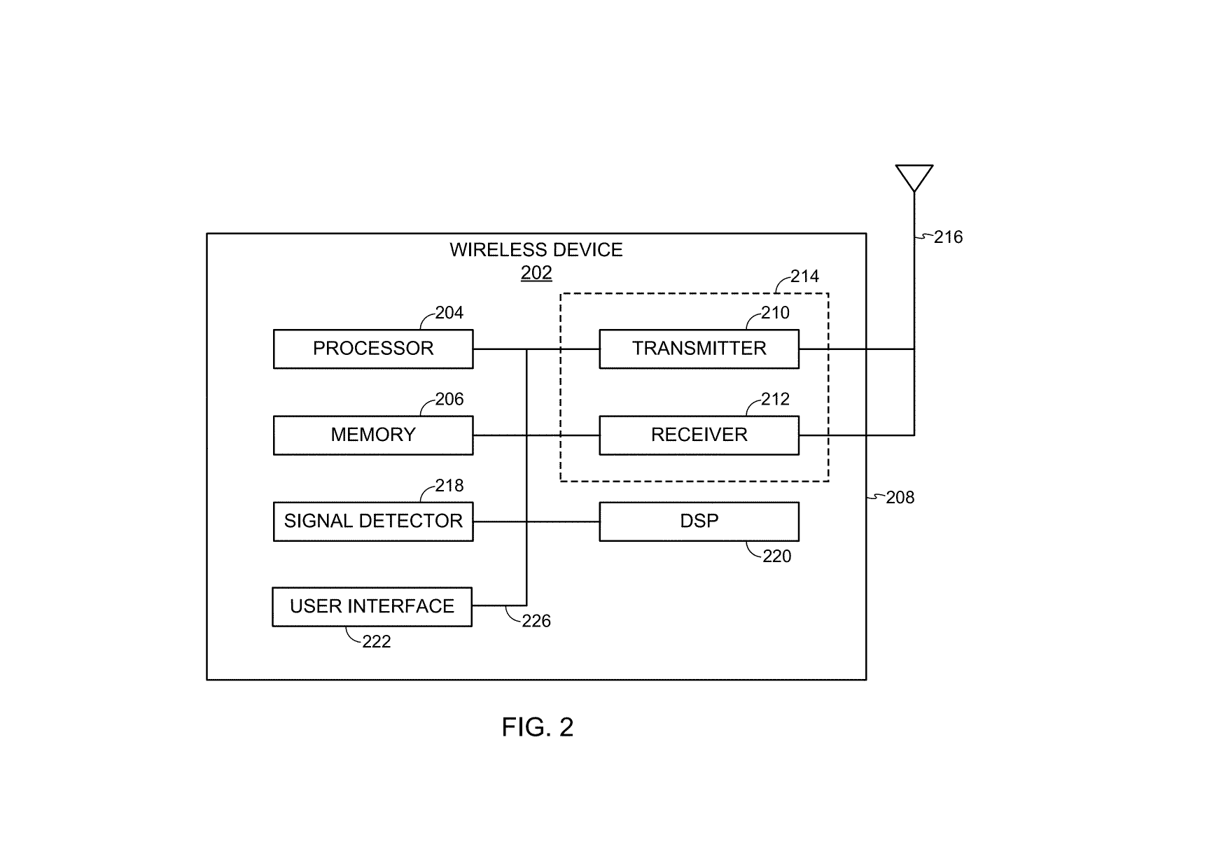

FIG. 2 illustrates various components that may be utilized in a wireless device 202 that may be employed within the wireless communication system 100. The wireless device 202 is an example of a device that may be configured to implement the various methods described herein. For example, the wireless device 202 may comprise the AP 104 or one of the STAs 106.

The wireless device 202 may include a processor 204 which controls operation of the wireless device 202. The processor 204 may also be referred to as a central processing unit (CPU). Memory 206, which may include both read-only memory (ROM) and random access memory (RAM), provides instructions and data to the processor 204. A portion of the memory 206 may also include non-volatile random access memory (NVRAM). The processor 204 typically performs logical and arithmetic operations based on program instructions stored within the memory 206. The instructions in the memory 206 may be executable to implement the methods described herein.

The processor 204 may comprise or be a component of a processing system implemented with one or more processors. The one or more processors may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that can perform calculations or other manipulations of information.

The processing system may also include machine-readable media for storing software. Software shall be construed broadly to mean any type of instructions, whether referred to as software, firmware, middleware, microcode, hardware description language, or otherwise. Instructions may include code (e.g., in source code format, binary code format, executable code format, or any other suitable format of code). The instructions, when executed by the one or more processors, cause the processing system to perform the various functions described herein.

The wireless device 202 may also include a housing 208 that may include a transmitter 210 and a receiver 212 to allow transmission and reception of data between the wireless device 202 and a remote location. The transmitter 210 and receiver 212 may be combined into a transceiver 214. An antenna 216 may be attached to the housing 208 and electrically coupled to the transceiver 214. The wireless device 202 may also include (not shown) multiple transmitters, multiple receivers, multiple transceivers, and/or multiple antennas.

The wireless device 202 may also include a signal detector 218 that may be used in an effort to detect and quantify the level of signals received by the transceiver 214. The signal detector 218 may detect such signals as total energy, energy per subcarrier per symbol, power spectral density and other signals. The wireless device 202 may also include a digital signal processor (DSP) 220 for use in processing signals. The DSP 220 may be configured to generate a data unit for transmission. In some aspects, the data unit may comprise a physical layer data unit (PPDU). In some aspects, the PPDU is referred to as a packet.

The wireless device 202 may further comprise a user interface 222 in some aspects. The user interface 222 may comprise a keypad, a microphone, a speaker, and/or a display. The user interface 222 may include any element or component that conveys information to a user of the wireless device 202 and/or receives input from the user.

The various components of the wireless device 202 may be coupled together by a bus system 226. The bus system 226 may include a data bus, for example, as well as a power bus, a control signal bus, and a status signal bus in addition to the data bus. Those of skill in the art will appreciate the components of the wireless device 202 may be coupled together or accept or provide inputs to each other using some other mechanism.

Although a number of separate components are illustrated in FIG. 2, those of skill in the art will recognize that one or more of the components may be combined or commonly implemented. For example, the processor 204 may be used to implement not only the functionality described above with respect to the processor 204, but also to implement the functionality described above with respect to the signal detector 218 and/or the DSP 220. Further, each of the components illustrated in FIG. 2 may be implemented using a plurality of separate elements.

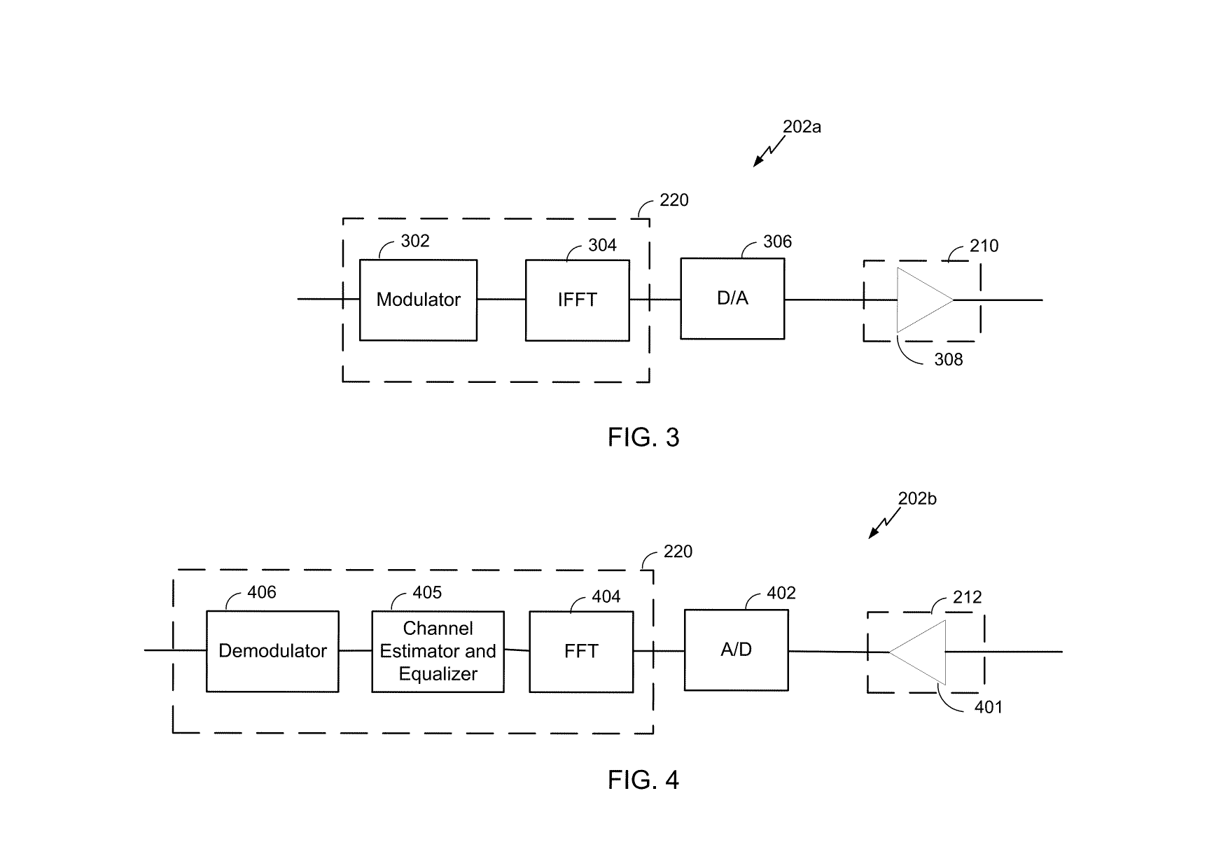

As discussed above, the wireless device 202 may comprise an AP 104 or an STA 106, and may be used to transmit and/or receive communications. FIG. 3 illustrates various components that may be utilized in the wireless device 202 to transmit wireless communications. The components illustrated in FIG. 3 may be used, for example, to transmit OFDM communications. In some aspects, the components illustrated in FIG. 3 are used to transmit data units with training fields with peak-to-power average ratio is as low as possible, as will be discussed in additional detail below. For ease of reference, the wireless device 202 configured with the components illustrated in FIG. 3 is hereinafter referred to as a wireless device 202a.

The wireless device 202a may comprise a modulator 302 configured to modulate bits for transmission. For example, the modulator 302 may determine a plurality of symbols from bits received from the processor 204 or the user interface 222, for example by mapping bits to a plurality of symbols according to a constellation. The bits may correspond to user data or to control information. In some aspects, the bits are received in codewords. In one aspect, the modulator 302 comprises a QAM (quadrature amplitude modulation) modulator, for example a 16-QAM modulator or a 64-QAM modulator. In other aspects, the modulator 302 comprises a binary phase-shift keying (BPSK) modulator or a quadrature phase-shift keying (QPSK) modulator.

The wireless device 202a may further comprise a transform module 304 configured to convert symbols or otherwise modulated bits from the modulator 302 into a time domain. In FIG. 3, the transform module 304 is illustrated as being implemented by an inverse fast Fourier transform (IFFT) module. In some implementations, there may be multiple transform modules (not shown) that transform units of data of different sizes.

In FIG. 3, the modulator 302 and the transform module 304 are illustrated as being implemented in the DSP 220. In some aspects, however, one or both of the modulator 302 and the transform module 304 are implemented in the processor 204 or in another element of the wireless device 202.

As discussed above, the DSP 220 may be configured to generate a data unit for transmission. In some aspects, the modulator 302 and the transform module 304 may be configured to generate a data unit comprising a plurality of fields including control information and a plurality of data symbols. The fields including the control information may comprise one or more training fields, for example, and one or more signal (SIG) fields. Each of the training fields may include a known sequence of bits or symbols. Each of the SIG fields may include information about the data unit, for example a description of a length or data rate of the data unit.

Returning to the description of FIG. 3, the wireless device 202a may further comprise a digital to analog converter 306 configured to convert the output of the transform module into an analog signal. For example, the time-domain output of the transform module 306 may be converted to a baseband OFDM signal by the digital to analog converter 306. The digital to analog converter 306 may be implemented in the processor 204 or in another element of the wireless device 202. In some aspects, the digital to analog converter 306 is implemented in the transceiver 214 or in a data transmit processor.

The analog signal may be wirelessly transmitted by the transmitter 210. The analog signal may be further processed before being transmitted by the transmitter 210, for example by being filtered or by being upconverted to an intermediate or carrier frequency. In the aspect illustrated in FIG. 3, the transmitter 210 includes a transmit amplifier 308. Prior to being transmitted, the analog signal may be amplified by the transmit amplifier 308. In some aspects, the amplifier 308 comprises a low noise amplifier (LNA).

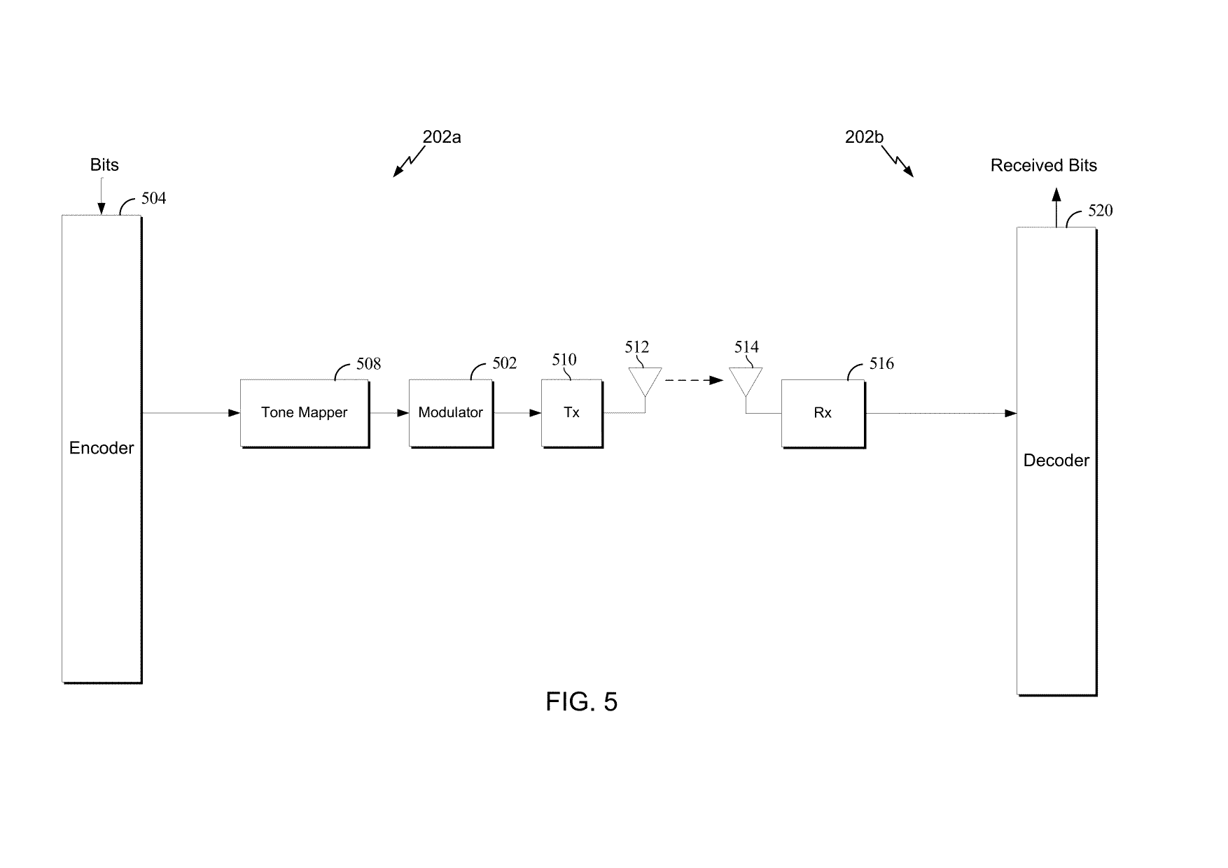

The transmitter 210 is configured to transmit one or more packets or data units in a wireless signal based on the analog signal. The data units may be generated using the processor 204 and/or the DSP 220, for example using the modulator 302 and the transform module 304 as discussed above. Data units that may be generated and transmitted as discussed above are described in additional detail below with respect to FIGS. 5-10.

FIG. 4 illustrates various components that may be utilized in the wireless device 202 to receive wireless communications. The components illustrated in FIG. 4 may be used, for example, to receive OFDM communications. In some aspects, the components illustrated in FIG. 4 are used to receive data units that include one or more training fields, as will be discussed in additional detail below. For example, the components illustrated in FIG. 4 may be used to receive data units transmitted by the components discussed above with respect to FIG. 3. For ease of reference, the wireless device 202 configured with the components illustrated in FIG. 4 is hereinafter referred to as a wireless device 202b.

The receiver 212 is configured to receive one or more packets or data units in a wireless signal. Data units that may be received and decoded or otherwise processed as discussed below are described in additional detail with respect to FIG. 5.

In the aspect illustrated in FIG. 4, the receiver 212 includes a receive amplifier 401. The receive amplifier 401 may be configured to amplify the wireless signal received by the receiver 212. In some aspects, the receiver 212 is configured to adjust the gain of the receive amplifier 401 using an automatic gain control (AGC) procedure. In some aspects, the automatic gain control uses information in one or more received training fields, such as a received short training field (STF) for example, to adjust the gain. Those having ordinary skill in the art will understand methods for performing AGC. In some aspects, the amplifier 401 comprises an LNA.

The wireless device 202b may comprise an analog to digital converter 402 configured to convert the amplified wireless signal from the receiver 212 into a digital representation thereof. Further to being amplified, the wireless signal may be processed before being converted by the digital to analog converter 402, for example by being filtered or by being downconverted to an intermediate or baseband frequency. The analog to digital converter 402 may be implemented in the processor 204 or in another element of the wireless device 202. In some aspects, the analog to digital converter 402 is implemented in the transceiver 214 or in a data receive processor.

The wireless device 202b may further comprise a transform module 404 configured to convert the representation the wireless signal into a frequency spectrum. In FIG. 4, the transform module 404 is illustrated as being implemented by a fast Fourier transform (FFT) module. In some aspects, the transform module may identify a symbol for each point that it uses.

The wireless device 202b may further comprise a channel estimator and equalizer 405 configured to form an estimate of the channel over which the data unit is received, and to remove certain effects of the channel based on the channel estimate. For example, the channel estimator may be configured to approximate a function of the channel, and the channel equalizer may be configured to apply an inverse of that function to the data in the frequency spectrum.

In some aspects, the channel estimator and equalizer 405 uses information in one or more received training fields, such as a long training field (LTF) for example, to estimate the channel. The channel estimate may be formed based on one or more LTFs received at the beginning of the data unit. This channel estimate may thereafter be used to equalize data symbols that follow the one or more LTFs. After a certain period of time or after a certain number of data symbols, one or more additional LTFs may be received in the data unit. The channel estimate may be updated or a new estimate formed using the additional LTFs. This new or update channel estimate may be used to equalize data symbols that follow the additional LTFs. In some aspects, the new or updated channel estimate is used to re-equalize data symbols preceding the additional LTFs. Those having ordinary skill in the art will understand methods for forming a channel estimate.

The wireless device 202b may further comprise a demodulator 406 configured to demodulate the equalized data. For example, the demodulator 406 may determine a plurality of bits from symbols output by the transform module 404 and the channel estimator and equalizer 405, for example by reversing a mapping of bits to a symbol in a constellation. The bits may be processed or evaluated by the processor 204, or used to display or otherwise output information to the user interface 222. In this way, data and/or information may be decoded. In some aspects, the bits correspond to codewords. In one aspect, the demodulator 406 comprises a QAM (quadrature amplitude modulation) demodulator, for example a 16-QAM demodulator or a 64-QAM demodulator. In other aspects, the demodulator 406 comprises a binary phase-shift keying (BPSK) demodulator or a quadrature phase-shift keying (QPSK) demodulator.

In FIG. 4, the transform module 404, the channel estimator and equalizer 405, and the demodulator 406 are illustrated as being implemented in the DSP 220. In some aspects, however, one or more of the transform module 404, the channel estimator and equalizer 405, and the demodulator 406 are implemented in the processor 204 or in another element of the wireless device 202.

As discussed above, the wireless signal received at the receiver 212 comprises one or more data units. Using the functions or components described above, the data units or data symbols therein may be decoded evaluated or otherwise evaluated or processed. For example, the processor 204 and/or the DSP 220 may be used to decode data symbols in the data units using the transform module 404, the channel estimator and equalizer 405, and the demodulator 406.

Data units exchanged by the AP 104 and the STA 106 may include control information or data, as discussed above. At the physical (PHY) layer, these data units may be referred to as physical layer protocol data units (PPDUs). In some aspects, a PPDU may be referred to as a packet or physical layer packet. Each PPDU may comprise a preamble and a payload. The preamble may include training fields and a SIG field. The payload may comprise a Media Access Control (MAC) header or data for other layers, and/or user data, for example. The payload may be transmitted using one or more data symbols. The systems, methods, and devices herein may utilize data units with training fields whose peak-to-power ratio has been minimized.

When using OFDM, information may be transmitted using a number of orthogonal subcarriers of the frequency band. The number of subcarriers that are used may depend on a variety of considerations including the available frequency bands for use, bandwidth and any associated regulatory constraints. The number of subcarriers used is correlated to the size of an FFT module as each modulated subcarrier is an input to an IFFT module to create the OFDM signal to be transmitted (e.g., a 32 point size FFT or IFFT may be used when the number of subcarriers is 32, etc.). As such, in some implementations a larger FFT size (e.g., 64, 128, 256, 512, etc.) may, corresponding to transmitting data using more subcarriers, be desired to achieve a larger bandwidth. In other implementations, a smaller FFT size may be used for transmitting data in a narrow bandwidth. The number of subcarriers, and therefore FFT size, may be chosen so as to comply with regulatory domains with certain bandwidth restrictions. For example, an FFT size of 32 may be provided for certain implementations (e.g., for down clocked implementations), and provided for use for 802.11ah. As such, the wireless device 202a may include several transform modules 304 implemented as an FFT or IFFT module, each of different sizes so as to comply with the number of subcarriers specified to be used. At least one of the transform modules 304 may be a 32 point size IFFT or FFT module according to certain aspects described herein.

Given lossy wireless communication mediums, various components may be included within a wireless communication device 200 to ensure that signals can be largely recovered correctly. One technique is the use of error correction. With error correction, when a bit or bits are lost, they might be recovered using other bits that were not lost according to whatever error correction coding was done. An example error correction code that may be used is a low-density parity-check (LDPC) code. LDPC codes represent forward error-correction codes that may provide error-rate performance very close to channel capacity, which represents a lower bound for wireless transmissions.

FIG. 5 is a functional block diagram of a system that may be implemented in wireless devices such as the wireless device of FIG. 2 to transmit and receive wireless communications. Bits to be transmitted are provided to an encoder 504 that may apply a forward error correcting (FEC) code on a bit stream that is to be received at an output of the receiver 202b. The FEC code may be a block code, a convolutional code, or the like. As an example, the FEC code may be an LDPC code. The encoded bits are provided to a tone mapper 508.

The following abbreviations may be used below in conjunction with describing the interleaving system:

N_{CBPS′}: Number of coded bits per symbol;

L_{CW}: Length of an LDPC codeword;

D_{TM}: LDPC tone mapping distance; and

N_{SD}: Number of subcarriers.

The tone mapper 508 allows the system to achieve full frequency diversity without any extra delay on the receive side caused by bit de-interleaving. In some cases, the L_{CW} may be significantly smaller than the N_{CBPS}. Because of this, without the tone mapper 508, the coded bits for each LDPC codeword may be transmitted through only a fraction of the tones, which could result in errors due to fading or other channel conditions occurring in large blocks. The tone mapper 508 may map consecutive symbols to different data tones so that errors may be recovered due to fading or other channel conditions. As an example, the tone mapper 508 may map consecutive symbols to data tones that are separated by at least D_{TM}−1 other data tones. The value of D_{TM} is described in greater detail below. In this way, the coded bits for each LDPC codeword may be transmitted through a broader sampling of the tones even if the length of the LDPC codeword is much smaller than the number of coded bits per symbol.

In one embodiment, about a 1 MHz OFDM transmission mode (e.g., a transmission with a frequency within 5 KHz of 1 MHz, etc.) may be used. Within the about 1 MHz transmission mode, 32 orthogonal subcarriers may be available. A 32 point FFT module and/or IFFT module may be used for the 32 orthogonal subcarriers. In one aspect, out of the 32 possible subcarriers, 24 subcarriers (i.e., tones) may be used to transmit data while the remaining tones may be used for pilot tones, a DC tone, and guard tones. As such, the tone mapper 508 may be optimized for 24 data tones according to various embodiments. In one aspect, the D_{TM} may be based on the number of data tones (i.e., 24). Generally, the tone mapper 508 may set the D_{TM} to be at least as large as N_{CBPS}/L_{CW} so that each LDPC codeword covers the full range of data tones. The D_{TM} may be an integer divisor of the N_{SD}. For example, for about a 1 MHz transmission mode with 24 data tones, the D_{TM} may be selected from the group of 2, 3, and 4.

In another embodiment, about a 2 MHz OFDM transmission mode (e.g., a transmission with a frequency within 10 KHz of 2 MHz, etc.) may be used. As an example, for about a 2 MHz transmission mode using a 64 point FFT module having 64 possible subcarriers, the D_{TM} may be 4.

In another embodiment, about a 4 MHz OFDM transmission mode (e.g., a transmission with a frequency within 20 KHz of 4 MHz, etc.) may be used. As an example, for about a 4 MHz transmission mode using a 128 point FFT module having 128 possible subcarriers, the D_{TM} may be 6.

In another embodiment, about a 8 MHz OFDM transmission mode (e.g., a transmission with a frequency within 40 KHz of 8 MHz, etc.) may be used. As an example, for about a 8 MHz transmission mode using a 256 point FFT module having 256 possible subcarriers, the D_{TM} may be 9.

The D_{TM} may be constant over all rates within each bandwidth so that a tone de-mapper (not shown) can be implemented at the receiver 202b at an FFT block, such as the transform module 404 illustrated in FIG. 4, with fixed tone processing.

The transmit stream may then be modulated by a modulator 502 and passed to a transmission circuit 510 that transmits the modulated transmit stream using an antenna 512 into a wireless radio space using some frequency band such as 1 MHz and others used for 802.11 transmissions. The bits may be modulated using QPSK (Quaternary Phase Shift Keying) modulation, BPSK (mapping one bit at a time), 16-QAM (mapping group of six bits, and the like.

In some embodiments, antenna 512 is a distinct and spatially separated antenna. In other embodiments, distinct signals might be combined into different polarizations off of fewer than M antennas. An example of this is where spatial rotation or spatial spreading is done, where multiple spatial streams are mapped on a single antenna. In any case, it should be understood that distinct spatial streams can be organized in different manners. For example, a transmit antenna might carry data from more than one spatial stream or several transmit antennas might carry data from a spatial stream. For example, consider the case of a transmitter with four transmit antennas and two spatial streams. Each spatial stream can be mapped onto two transmit antennas in that case, so two antennas are carrying data from just one spatial stream.

A receiver 202b receives signals from the channel at antenna 514, which is coupled to receive circuit 516. The output of receive circuit 516 is provided to a decoder 520, which in turn outputs the received bits which, without unrecoverable errors, are the same as the transmitted bits input to encoder 504. In some embodiments, the output of the receive circuit 516 is provided to a demodulator (not shown), which may perform the reverse operations as the modulator 502 described above. In further embodiments, the output of the demodulator is provided to the tone de-mapper (not shown), which may perform the reverse operations as the tone mapper 508 described above. The output of the tone de-mapper may then be provided to the decoder 520.

The same system described above may operate in a MIMO transmission. In such a transmission, multiple tone mappers 508, modulators 502, transmission circuits 510, antennas 512, antennas 514, and receive circuits 516 may be present to account for each transmit stream.

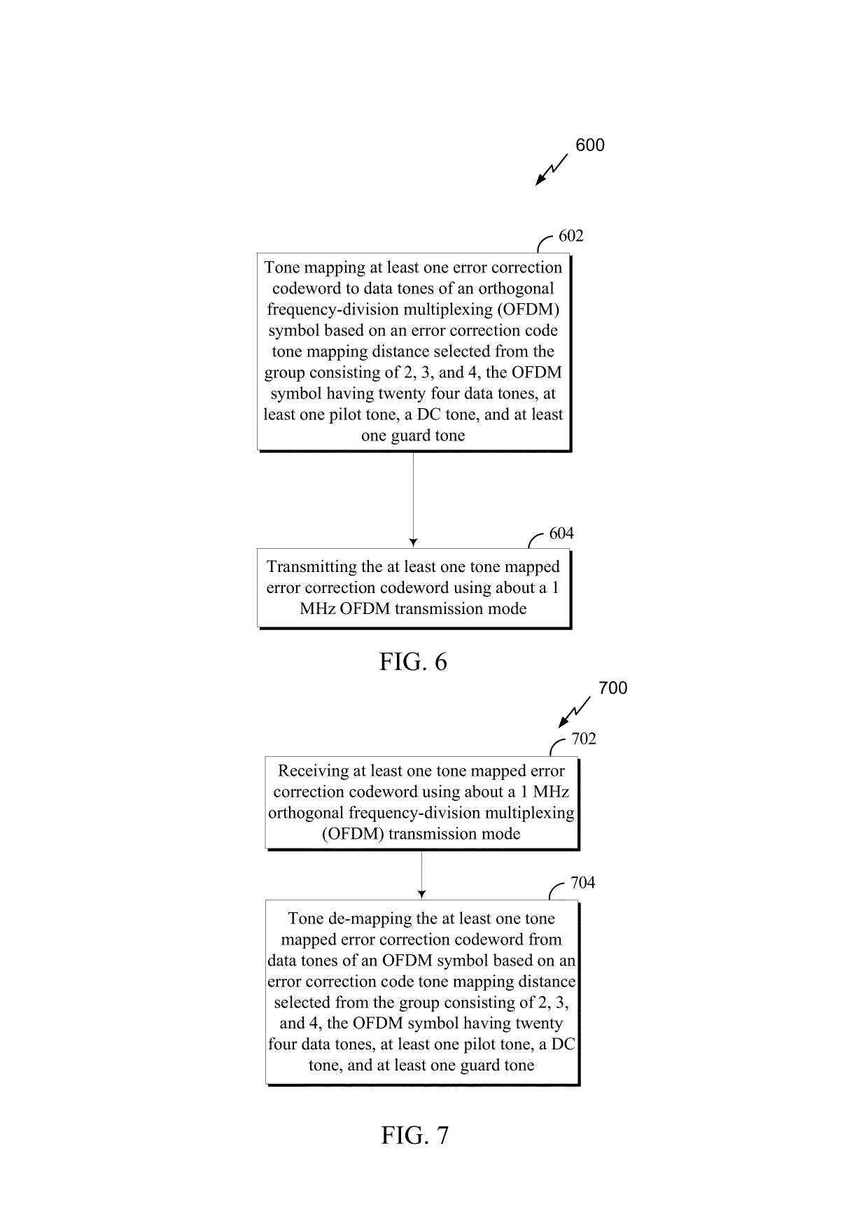

FIG. 6 shows a flowchart of an exemplary method 600 for tone mapping for transmission using about a 1 MHz OFDM transmission mode. In block 602, the method 600 includes tone mapping at least one error correction codeword to data tones of an OFDM symbol based on an error correction code tone mapping distance selected from the group consisting of 2, 3, and 4. In an embodiment, the at least one error correction codeword is at least one LDPC codeword. In a further embodiment, the error correction code tone mapping distance is an LDPC tone mapping distance. The OFDM symbol has twenty four data tones, at least one pilot tone, a DC tone, and at least one guard tone. In block 604, the method 600 further includes transmitting the at least one tone mapped error correction codeword using about a 1 MHz OFDM transmission mode.

FIG. 7 shows a flowchart of an exemplary method 700 for receiving and tone de-mapping a data unit. In block 702, the method 700 includes receiving at least one tone mapped error correction codeword using about a 1 MHz OFDM transmission mode. In an embodiment, the at least one tone mapped error correction codeword is at least one tone mapped LDPC codeword. In block 704, the method 700 further includes tone de-mapping the at least one tone mapped error correction codeword from data tones of an OFDM symbol based on an error correction code tone mapping distance selected from the group consisting of 2, 3, and 4, where the OFDM symbol has twenty four data tones, at least one pilot tone, a DC tone, and at least one guard tone. In an embodiment, the error correction code tone mapping distance is an LDPC tone mapping distance.

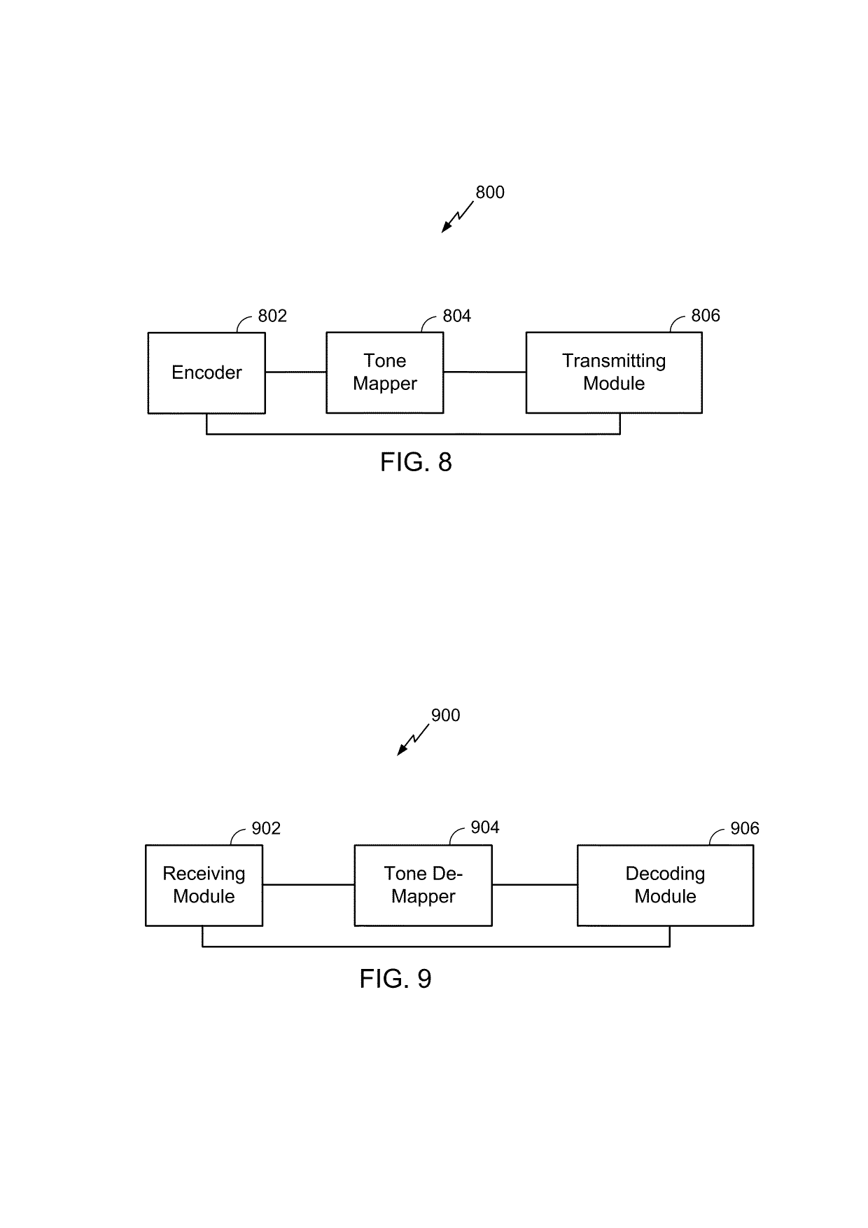

FIG. 8 is a functional block diagram of another exemplary wireless device 800 that may be employed within the wireless communication system 100. Those skilled in the art will appreciate that a wireless communication device may have more components than the wireless communication device shown in FIG. 8. The wireless communication device 800 shown includes only those components useful for describing some prominent features of certain implementations. The device 800 includes an encoder 802 for encoding data for wireless transmission. In some cases a means for encoding may include the encoder 802. The device 800 further includes a tone mapper 804 for tone mapping the encoded data from the encoder 802 for transmission. The tone mapper 804 may be configured to perform one or more of the functions discussed above with respect to the block 602 illustrated in FIG. 6. In some cases a means for tone mapping may include the tone mapper 804. The device 800 further comprises a transmitting module 806 for wirelessly transmitting the output from the tone mapper. The transmitting module 806 may be configured to perform one or more of the functions discussed above with respect to the block 604 illustrated in FIG. 6. The transmitting module 804 may correspond to the transmitter 210. In some cases, a means for transmitting may include the transmitting module 806. The transmitting module 806 may include a variety of components including, but not limited to, a constellation mapper, a modulator, an IDFT (inverse discrete time fourier transform module or IFFT 304 as described above with reference to FIG. 3), a digital to analog converter, an amplifier, an antenna, and other components.

FIG. 9 is a functional block diagram of yet another exemplary wireless device 900 that may be employed within the wireless communication system 100. The device 900 comprises a receiving module 902 for wirelessly receiving data. The receiving module 902 may be configured to perform one or more of the functions discussed above with respect to the block 702 illustrated in FIG. 7. The receiving module 902 may correspond to the receiver 212, and may include the amplifier 401. In some cases, a means for receiving may include the receiving module 902. The device 900 further comprises a tone de-mapper 904 that tone de-maps received data. The tone de-mapper 904 may be configured to perform one or more of the functions discussed above with respect to the block 704 illustrated in FIG. 7. In some cases a means for tone de-mapping may include the tone de-mapper 904.

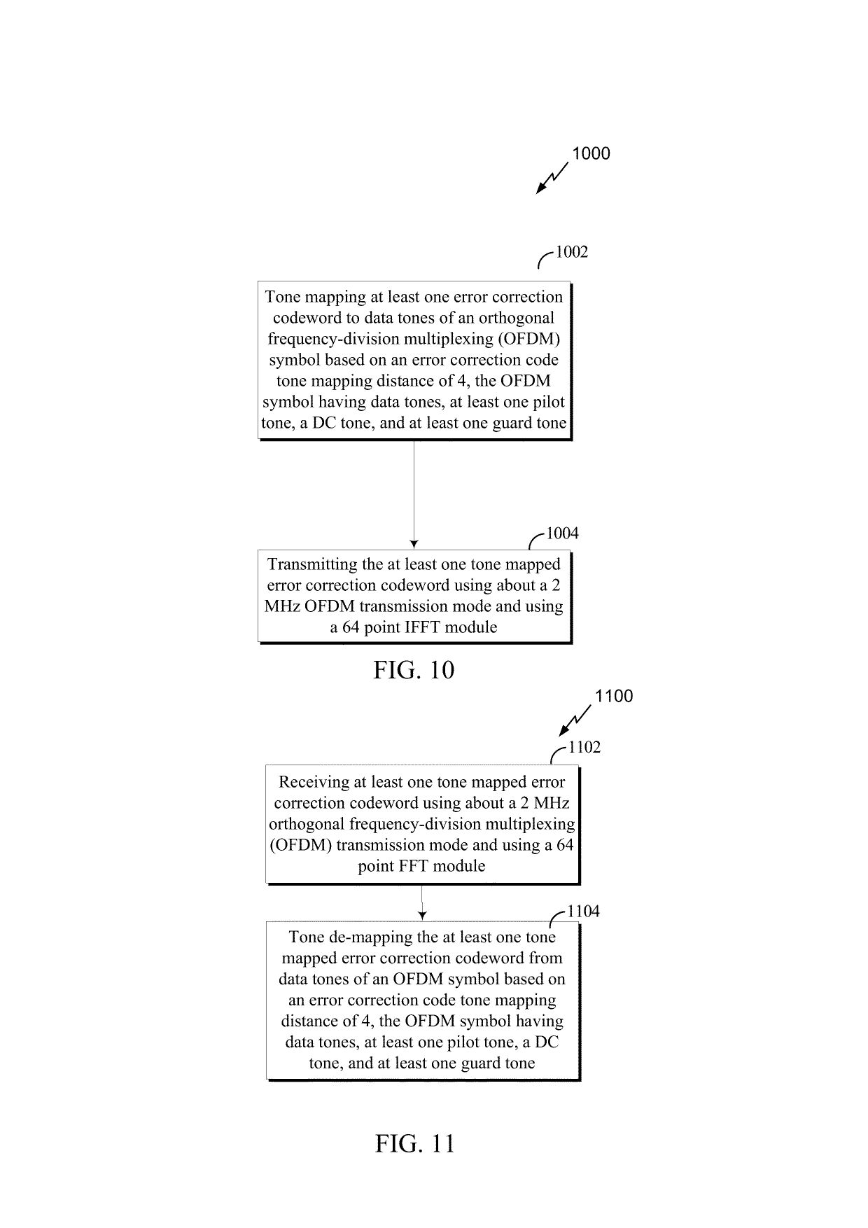

FIG. 10 shows a flowchart of an exemplary method 1000 for tone mapping for transmission using about a 2 MHz OFDM transmission mode. In block 1002, the method 1000 includes tone mapping at least one error correction codeword to data tones of an OFDM symbol based on an error correction code tone mapping distance of 4. In an embodiment, the at least one error correction codeword is at least one LDPC codeword. In a further embodiment, the error correction code tone mapping distance is an LDPC tone mapping distance. The OFDM symbol has data tones, at least one pilot tone, a DC tone, and at least one guard tone. In block 1004, the method 1000 further includes transmitting the at least one tone mapped error correction codeword using about a 2 MHz OFDM transmission mode and using a 64 point IFFT module.

FIG. 11 shows a flowchart of an exemplary method 1100 for receiving and tone de-mapping a data unit. In block 1102, the method 1100 includes receiving at least one tone mapped error correction codeword using about a 2 MHz OFDM transmission mode and using a 64 point FFT module. in an embodiment, the at least one tone mapped error correction codeword is at least one tone mapped LDPC codeword. In block 1104, the method 1100 further includes tone de-mapping the at least one tone mapped error correction codeword from data tones of an OFDM symbol based on an error correction code tone mapping distance of 4, where the OFDM symbol has data tones, at least one pilot tone, a DC tone, and at least one guard tone. In an embodiment, the error correction code tone mapping distance is an LDPC tone mapping distance.

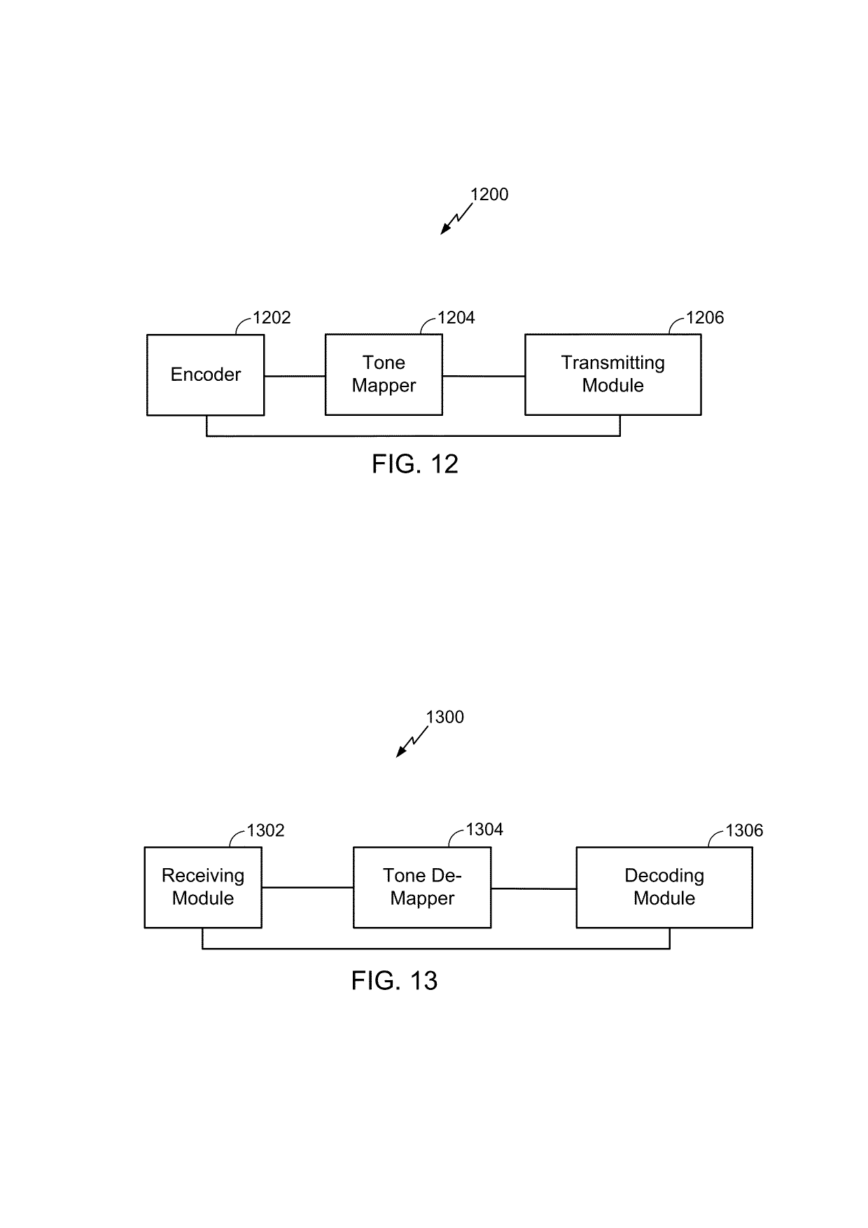

FIG. 12 is a functional block diagram of another exemplary wireless device 1200 that may be employed within the wireless communication system 100. Those skilled in the art will appreciate that a wireless communication device may have more components than the wireless communication device shown in FIG. 12. The wireless communication device 1200 shown includes only those components useful for describing some prominent features of certain implementations. The device 1200 includes an encoder 1202 for encoding data for wireless transmission. In some cases a means for encoding may include the encoder 1202. The device 1200 further includes a tone mapper 1204 for tone mapping the encoded data from the encoder 1202 for transmission. The tone mapper 1204 may be configured to perform one or more of the functions discussed above with respect to the block 1002 illustrated in FIG. 10. In some cases a means for tone mapping may include the tone mapper 1204. The device 1200 further comprises a transmitting module 1206 for wirelessly transmitting the output from the tone mapper. The transmitting module 1206 may be configured to perform one or more of the functions discussed above with respect to the block 1004 illustrated in FIG. 10. The transmitting module 1204 may correspond to the transmitter 210. In some cases, a means for transmitting may include the transmitting module 1206. The transmitting module 1206 may include a variety of components including, but not limited to, a constellation mapper, a modulator, an IDFT (inverse discrete time fourier transform module or IFFT 304 as described above with reference to FIG. 3), a digital to analog converter, an amplifier, an antenna, and other components.

FIG. 13 is a functional block diagram of yet another exemplary wireless device 1300 that may be employed within the wireless communication system 100. The device 1300 comprises a receiving module 1302 for wirelessly receiving data. The receiving module 1302 may be configured to perform one or more of the functions discussed above with respect to the block 1102 illustrated in FIG. 11. The receiving module 902 may correspond to the receiver 212, and may include the amplifier 401. In some cases, a means for receiving may include the receiving module 1302. The device 1300 further comprises a tone de-mapper 1304 that de-maps received data. The tone de-mapper 1304 may be configured to perform one or more of the functions discussed above with respect to the block 1104 illustrated in FIG. 11. In some cases a means for tone de-mapping may include the tone de-mapper 1304.

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like. Further, a “channel width” as used herein may encompass or may also be referred to as a bandwidth in certain aspects.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various operations of methods described above may be performed by any suitable means capable of performing the operations, such as various hardware and/or software component(s), circuits, and/or module(s). Generally, any operations illustrated in the Figures may be performed by corresponding functional means capable of performing the operations.

The various illustrative logical blocks, modules and circuits described in connection with the present disclosure may be implemented or performed with a general purpose processor, a digital signal processor (DSP), an application specific integrated circuit (ASIC), a field programmable gate array signal (FPGA) or other programmable logic device (PLD), discrete gate or transistor logic, discrete hardware components or any combination thereof designed to perform the functions described herein. A general purpose processor may be a microprocessor, but in the alternative, the processor may be any commercially available processor, controller, microcontroller or state machine. A processor may also be implemented as a combination of computing devices, e.g., a combination of a DSP and a microprocessor, a plurality of microprocessors, one or more microprocessors in conjunction with a DSP core, or any other such configuration.

In one or more aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Thus, in some aspects computer readable medium may comprise non-transitory computer readable medium (e.g., tangible media). In addition, in some aspects computer readable medium may comprise transitory computer readable medium (e.g., a signal). Combinations of the above should also be included within the scope of computer-readable media.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware or any combination thereof. If implemented in software, the functions may be stored as one or more instructions on a computer-readable medium. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, include compact disc (CD), laser disc, optical disc, digital versatile disc (DVD), floppy disk, and Blu-ray® disc where disks usually reproduce data magnetically, while discs reproduce data optically with lasers.

Thus, certain aspects may comprise a computer program product for performing the operations presented herein. For example, such a computer program product may comprise a computer readable medium having instructions stored (and/or encoded) thereon, the instructions being executable by one or more processors to perform the operations described herein. For certain aspects, the computer program product may include packaging material.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

Further, it should be appreciated that modules and/or other appropriate means for performing the methods and techniques described herein can be downloaded and/or otherwise obtained by a user terminal and/or base station as applicable. For example, such a device can be coupled to a server to facilitate the transfer of means for performing the methods described herein. Alternatively, various methods described herein can be provided via storage means (e.g., RAM, ROM, a physical storage medium such as a compact disc (CD) or floppy disk, etc.), such that a user terminal and/or base station can obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes and variations may be made in the arrangement, operation and details of the methods and apparatus described above without departing from the scope of the claims.

While the foregoing is directed to aspects of the present disclosure, other and further aspects of the disclosure may be devised without departing from the basic scope thereof, and the scope thereof is determined by the claims that follow.

What is claimed is:

1. A wireless communications apparatus, comprising:
a tone mapper configured to tone map at least one error correction codeword to data tones of an orthogonal frequency-division multiplexing (OFDM) symbol based on an error correction code tone mapping distance selected from the group consisting of 2, 3, and 4, the OFDM symbol having twenty four data tones, at least one pilot tone, a DC tone, and at least one guard tone; and
a transmit module configured to transmit the at least one tone mapped error correction codeword using about a 1 MHz OFDM transmission mode.

2. The wireless communications apparatus of claim 1, wherein the at least one error correction codeword comprises at least one low-density parity check (LDPC) codeword, and wherein the error correction code tone mapping distance comprises an LDPC tone mapping distance.

3. The wireless communication apparatus of 2, wherein the LDPC tone mapping distance is based on a number of coded bits in the OFDM symbol and a length of the LDPC codeword.

4. The wireless communication apparatus of claim 2, wherein the tone mapper is further configured to tone map the at least one LDPC codeword, and wherein the transmit module comprises a modulator configured to modulate the at least one tone mapped LDPC codeword for transmission.

5. The wireless communications apparatus of claim 1, further comprising an encoder configured to provide encoded data to the tone mapper

6. A method for tone mapping data for wireless transmission, the method comprising:
tone mapping at least one error correction codeword to data tones of an orthogonal frequency-division multiplexing (OFDM) symbol based on an error correction code tone mapping distance selected from the group consisting of 2, 3, and 4, the OFDM symbol having twenty four data tones, at least one pilot tone, a DC tone, and at least one guard tone; and
transmitting the at least one tone mapped error correction codeword using about a 1 MHz OFDM transmission mode.

7. The method of claim 6, wherein the at least one error correction codeword comprises at least one low-density parity check (LDPC) codeword, and wherein the error correction code tone mapping distance comprises an LDPC tone mapping distance.

8. The method of claim 7, wherein tone mapping the at least one error correction codeword comprises tone mapping the at least one LDPC codeword based on a number of coded bits in the OFDM symbol and a length of the LDPC codeword.

9. The method of claim 8, further comprising modulating the at least one tone mapped LDPC codeword for transmission.

10. The method of claim 6, further comprising providing encoded data to an apparatus that performs the tone mapping.

11. A wireless communications apparatus, comprising:
means for tone mapping at least one error correction codeword to data tones of an orthogonal frequency-division multiplexing (OFDM) symbol based on an error correction code tone mapping distance selected from the group consisting of 2, 3, and 4, the OFDM symbol having twenty four data tones, at least one pilot tone, a DC tone, and at least one guard tone; and
means for transmitting the at least one tone mapped error correction codeword using about a 1 MHz OFDM transmission mode.

12. The method of claim 11, wherein the at least one error correction codeword comprises at least one low-density parity check (LDPC) codeword, and wherein the error correction code tone mapping distance comprises an LDPC tone mapping distance.

13. The wireless communications apparatus of claim 12, wherein means for tone mapping the at least one error correction codeword comprises means for tone mapping the at least one LDPC codeword based on a number of coded bits in the OFDM symbol and a length of the LDPC codeword.

14. The wireless communications apparatus of claim 13, further comprising means for modulating the at least one tone mapped LDPC codeword for transmission.

15. The wireless communications apparatus of claim 11, further comprising means for providing encoded data to the means for tone mapping.

16. The wireless communications apparatus of claim 11, wherein the means for tone mapping comprises a tone mapper.

17. The wireless communications apparatus of claim 11, wherein the means for transmitting comprises at least one antenna.

18. A non-transitory computer-readable medium comprising code that, when executed, causes an apparatus to:
tone map at least one error correction codeword to data tones of an orthogonal frequency-division multiplexing (OFDM) symbol based on an error correction code tone mapping distance selected from the group consisting of 2, 3, and 4, the OFDM symbol having twenty four data tones, at least one pilot tone, a DC tone, and at least one guard tone; and
transmit the at least one tone mapped error correction codeword using about a 1 MHz OFDM transmission mode.

19. The medium of claim 18, wherein the at least one error correction codeword comprises at least one low-density parity check (LDPC) codeword, and wherein the error correction code tone mapping distance comprises an LDPC tone mapping distance.

20. The medium of claim 19, further comprising code that, when executed, causes the apparatus to tone map the at least one LDPC codeword based on a number of coded bits in the OFDM symbol and a length of the LDPC codeword.

21. The medium of claim 20, further comprising code that, when executed, causes the apparatus to modulate the at least one tone mapped LDPC codeword for transmission.

22. The medium of claim 18, further comprising code that, when executed, causes the apparatus to provide encoded data to a tone mapper of the apparatus.

23. A wireless communications apparatus, comprising:
a receive module configured to receive at least one tone mapped error correction codeword using about a 1 MHz orthogonal frequency-division multiplexing (OFDM) transmission mode; and
a tone de-mapper configured to tone de-map the at least one tone mapped error correction codeword from data tones of an OFDM symbol based on an error correction code tone mapping distance selected from the group consisting of 2, 3, and 4, the OFDM symbol having twenty four data tones, at least one pilot tone, a DC tone, and at least one guard tone.

24. The wireless communications apparatus of claim 23, wherein the at least one tone mapped error correction codeword comprises at least one tone mapped low-density parity check (LDPC) codeword, and wherein the error correction code tone mapping distance comprises an LDPC tone mapping distance.

25. The wireless communications apparatus of claim 24, wherein the LDPC tone mapping distance is based on a number of coded bits in the OFDM symbol and a length of the LDPC codeword.

26. The wireless communications apparatus of claim 24, further comprising a decoder configured to decode an output from the tone de-mapper.

27. The wireless communication apparatus of claim 24, wherein the receive module comprises a demodulator configured to demodulate the at least one tone mapped LDPC codeword.

28. A method for tone de-mapping data, the method comprising:
receiving at least one tone mapped error correction codeword using about a 1 MHz orthogonal frequency-division multiplexing (OFDM) transmission mode; and
tone de-mapping the at least one tone mapped error correction codeword from data tones of an OFDM symbol based on an error correction code tone mapping distance selected from the group consisting of 2, 3, and 4, the OFDM symbol having twenty four data tones, at least one pilot tone, a DC tone, and at least one guard tone.

29. The method of claim 28, wherein the at least one tone mapped error correction codeword comprises at least one tone mapped low-density parity check (LDPC) codeword, and wherein the error correction code tone mapping distance comprises an LDPC tone mapping distance.

30. The method of claim 29, wherein tone de-mapping the at least one tone mapped error correction codeword comprises tone de-mapping the at least one tone mapped LDPC codeword based on a number of coded bits in the OFDM symbol and a length of the LDPC codeword.

31. The method of claim 29, further comprising decoding an output from an apparatus that performs the tone de-mapping.

32. The method of claim 29, further comprising demodulating the at least one tone mapped LDPC codeword.

33. A wireless communications apparatus, comprising:
means for receiving at least one tone mapped error correction codeword using a 1 MHz orthogonal frequency-division multiplexing (OFDM) transmission mode; and
means for tone de-mapping the at least one error correction codeword from data tones of an OFDM symbol based on an error correction code tone mapping distance selected from the group consisting of 2, 3, and 4, the OFDM symbol having twenty four data tones, at least one pilot tone, a DC tone, and at least one guard tone.

34. The wireless communications apparatus of claim 33, wherein the at least one tone mapped error correction codeword comprises at least one tone mapped low-density parity check (LDPC) codeword, and wherein the error correction code tone mapping distance comprises an LDPC tone mapping distance.

35. The wireless communications apparatus of claim 34, wherein means for tone de-mapping the at least one tone mapped error correction codeword comprises means for tone de-mapping the at least one tone mapped LDPC codeword based on a number of coded bits in the OFDM symbol and a length of the LDPC codeword.

36. The wireless communications apparatus of claim 34, further comprising means for demodulating the at least one tone mapped LDPC codeword.

37. The wireless communications apparatus of claim 34, further comprising means for decoding an output from the means for tone de-mapping.

38. The wireless communications apparatus of claim 33, wherein means for receiving comprises at least one antenna.

39. The wireless communications apparatus of claim 33, wherein means for tone de-mapping comprises a tone de-mapper.

40. A non-transitory computer-readable medium comprising code that, when executed, causes an apparatus to:
receive at least one tone mapped error correction codeword using about a 1 MHz orthogonal frequency-division multiplexing (OFDM) transmission mode; and
tone de-map the at least one tone mapped error correction codeword from data tones of an OFDM symbol based on an error correction code tone mapping distance selected from the group consisting of 2, 3, and 4, the OFDM symbol having twenty four data tones, at least one pilot tone, a DC tone, and at least one guard tone.

41. The medium of claim 40, wherein the at least one tone mapped error correction codeword comprises at least one tone mapped low-density parity check (LDPC) codeword, and wherein the error correction code tone mapping distance comprises an LDPC tone mapping distance.

42. The medium of claim 41, further comprising code that, when executed, causes the apparatus to tone de-map the at least one tone mapped LDPC codeword based on a number of coded bits in the OFDM symbol and a length of the LDPC codeword.

43. The medium of claim 41, further comprising code that, when executed, causes the apparatus to demodulate the at least one tone mapped LDPC codeword.

44. The wireless communications apparatus of claim 41, further comprising code that, when executed, causes the apparatus to decode an output from a tone de-mapper of the apparatus.

45. A wireless communications apparatus, comprising:
a tone mapper configured to tone map at least one error correction codeword to data tones of an orthogonal frequency-division multiplexing (OFDM) symbol based on an error correction code tone mapping distance of 4, the OFDM symbol having data tones, at least one pilot tone, a DC tone, and at least one guard tone; and
a transmit module configured to transmit the at least one tone mapped error correction codeword using about a 2 MHz OFDM transmission mode and using a 64 point IFFT module.

46. The wireless communications apparatus of claim 45, wherein the at least one error correction codeword comprises a low-density parity check (LDPC) codeword, and wherein the error correction code tone mapping distance comprises an LDPC tone mapping distance.

47. The wireless communications apparatus of claim 46, wherein the LDPC tone mapping distance is based on a number of coded bits in the OFDM symbol and a length of the LDPC codeword.

48. The wireless communications apparatus of claim 46, wherein the tone mapper is further configured to tone map the at least one LDPC codeword, and wherein the transmit module comprises a modulator configured to modulate the at least one tone mapped LDPC codeword for transmission.

49. The wireless communications apparatus of claim 45, further comprising an encoder configured to provide encoded data to the tone mapper.

50. A method for tone mapping data for wireless transmission, the method comprising:
tone mapping at least one error correction codeword to data tones of an orthogonal frequency-division multiplexing (OFDM) symbol based on an error correction tone mapping distance of 4, the OFDM symbol having data tones, at least one pilot tone, a DC tone, and at least one guard tone; and
transmitting the at least one tone mapped error correction codeword using about a 2 MHz OFDM transmission mode and using a 64 point IFFT module.

51. The method of claim 50, wherein the at least one error correction codeword comprises a low-density parity check (LDPC) codeword, and wherein the error correction code tone mapping distance comprises an LDPC tone mapping distance.

52. The method of claim 51, wherein tone mapping the at least one error correction codeword comprises tone mapping the at least one LDPC codeword based on a number of coded bits in the OFDM symbol and a length of the LDPC codeword.

53. The method of claim 52, further comprising modulating the at least one tone mapped LDPC codeword for transmission.

54. The method of claim 50, further comprising providing encoded data to an apparatus that performs the tone mapping.

55. A wireless communications apparatus, comprising:
means for tone mapping at least one error correction codeword to data tones of an orthogonal frequency-division multiplexing (OFDM) symbol based on an error correction code tone mapping distance of 4, the OFDM symbol having data tones, at least one pilot tone, a DC tone, and at least one guard tone; and
means for transmitting the at least one tone mapped error correction codeword using about a 2 MHz OFDM transmission mode and using a 64 point IFFT module.

56. The wireless communications apparatus of claim 55, wherein the at least one error correction codeword comprises a low-density parity check (LDPC) codeword, and wherein the error correction code tone mapping distance comprises an LDPC tone mapping distance.

57. The wireless communications apparatus of claim 56, wherein means for tone mapping the at least one error correction codeword comprises means for tone mapping the at least one LDPC codeword based on a number of coded bits in the OFDM symbol and a length of the LDPC codeword.

58. The wireless communications apparatus of claim 57, further comprising means for modulating the at least one tone mapped LDPC codeword for transmission.

59. The wireless communications apparatus of claim 55, further comprising means for providing encoded data to the means for tone mapping.

60. The wireless communications apparatus of claim 55, wherein the means for tone mapping comprises a tone mapper.

61. The wireless communications apparatus of claim 55, wherein the means for transmitting comprises at least one antenna.

62. A non-transitory computer-readable medium comprising code that, when executed, causes an apparatus to:
tone map at least one error correction codeword to data tones of an orthogonal frequency-division multiplexing (OFDM) symbol based on an error correction code tone mapping distance of 4, the OFDM symbol having data tones, at least one pilot tone, a DC tone, and at least one guard tone; and
transmit the at least one tone mapped error correction codeword using about a 2 MHz OFDM transmission mode and using a 64 point IFFT module.

63. The medium of claim 62, wherein the at least one error correction codeword comprises a low-density parity check (LDPC) codeword, and wherein the error correction code tone mapping distance comprises an LDPC tone mapping distance.

64. The medium of claim 63, further comprising code that, when executed, causes the apparatus to tone map the at least one LDPC codeword based on a number of coded bits in the OFDM symbol and a length of the LDPC codeword.

65. The medium of claim 64, further comprising code that, when executed, causes the apparatus to modulate the at least one tone mapped LDPC codeword for transmission.

66. The medium of claim 62, further comprising code that, when executed, causes the apparatus to provide encoded data to a tone mapper of the apparatus.

67. A wireless communications apparatus, comprising:
a receive module configured to receive at least one tone mapped error correction codeword using about a 2 MHz orthogonal frequency-division multiplexing (OFDM) transmission mode and using a 64 point FFT module; and
a tone de-mapper configured to tone de-map the at least one tone mapped error correction codeword from data tones of an OFDM symbol based on an error correction code tone mapping distance of 4, the OFDM symbol having data tones, at least one pilot tone, a DC tone, and at least one guard tone.

68. The wireless communications apparatus of claim 67, wherein the at least one tone mapped error correction codeword comprises at least one tone mapped low-density parity check (LDPC) codeword, and wherein the error correction code tone mapping distance comprises an LDPC tone mapping distance.

69. The wireless communications apparatus of claim 68, wherein the LDPC tone mapping distance is based on a number of coded bits in the OFDM symbol and a length of the LDPC codeword.

70. The wireless communication apparatus of claim 68, wherein the receive module comprises a demodulator configured to demodulate the at least one tone mapped LDPC codeword.

71. The wireless communications apparatus of claim 67, further comprising a decoder configured to decode an output from the tone de-mapper.

72. A method for tone de-mapping data, the method comprising:
receiving at least one tone mapped error correction codeword using about a 2 MHz orthogonal frequency-division multiplexing (OFDM) transmission mode and using a 64 point FFT module; and
tone de-mapping the at least one tone mapped error correction codeword from data tones of an OFDM symbol based on an LDPC tone mapping distance of 4, the OFDM symbol having data tones, at least one pilot tone, a DC tone, and at least one guard tone.

73. The method of claim 72, wherein the at least one tone mapped error correction codeword comprises at least one tone mapped low-density parity check (LDPC) codeword, and wherein the error correction code tone mapping distance comprises an LDPC tone mapping distance.

74. The method of claim 73, wherein tone de-mapping the at least one tone mapped error correction codeword comprises tone de-mapping the at least one tone mapped LDPC codeword based on a number of coded bits in the OFDM symbol and a length of the LDPC codeword.

75. The method of claim 73, further comprising demodulating the at least one tone mapped LDPC codeword.

76. The method of claim 72, further comprising decoding an output from an apparatus that performs the tone de-mapping.

77. A wireless communications apparatus, comprising:
means for receiving at least one tone mapped error correction (LDPC) codeword using about a 2 MHz orthogonal frequency-division multiplexing (OFDM) transmission mode and using a 64 point FFT module; and
means for tone de-mapping the at least one tone mapped error correction codeword from data tones of an OFDM symbol based on an error correction code tone mapping distance of 4, the OFDM symbol having data tones, at least one pilot tone, a DC tone, and at least one guard tone.

78. The wireless communications apparatus of claim 77, wherein the at least one tone mapped error correction codeword comprises at least one tone mapped low-density parity check (LDPC) codeword, and wherein the error correction code tone mapping distance comprises an LDPC tone mapping distance.

79. The wireless communications apparatus of claim 78, wherein means for tone de-mapping the at least one tone mapped error correction codeword comprises means for tone de-mapping the at least one tone mapped LDPC codeword based on a number of coded bits in the OFDM symbol and a length of the LDPC codeword.

80. The wireless communications apparatus of claim 78, further comprising means for demodulating the at least one tone mapped LDPC codeword.

81. The wireless communications apparatus of claim 77, further comprising means for decoding an output from an apparatus that performs the tone de-mapping.

82. The wireless communications apparatus of claim 77, wherein means for receiving comprises at least one antenna.

83. The wireless communications apparatus of claim 77, wherein means for tone de-mapping comprises a tone de-mapper.

84. A non-transitory computer-readable medium comprising code that, when executed, causes an apparatus to:
receive at least one tone mapped error correction codeword using about a 2 MHz orthogonal frequency-division multiplexing (OFDM) transmission mode and using a 64 point FFT module; and
tone de-map the at least one tone mapped error correction codeword from data tones of an OFDM symbol based on an error correction code tone mapping distance of 4, the OFDM symbol having four data tones, at least one pilot tone, a DC tone, and at least one guard tone.

85. The medium of claim 84, wherein the at least one tone mapped error correction codeword comprises at least one tone mapped low-density parity check (LDPC) codeword, and wherein the error correction code tone mapping distance comprises an LDPC tone mapping distance.

86. The medium of claim 85, further comprising code that, when executed, causes the apparatus to tone de-map the at least one tone mapped LDPC codeword based on a number of coded bits in the OFDM symbol and a length of the LDPC codeword.

87. The medium of claim 85, further comprising code that, when executed, causes the apparatus to demodulate the at least one tone mapped LDPC codeword.

88. The medium of claim 84, further comprising code that, when executed, causes an apparatus to decode an output from an apparatus that performs the tone de-mapping
